(19) United States
(12) Patent Application Publication
(10) Pub. No.: US 2018/0206362 A1
(43) Pub. Date: Jul. 19, 2018

(54) APPARATUS AND METHOD FOR REMOVING HEAT FROM A HEAT-GENERATING DEVICE

(71) Applicant: Ventiva, Inc., Milpitas, CA (US)

(72) Inventors: Rudy Vadillo, Gilroy, CA (US); Gary Alfred Oliverio, San Jose, CA (US)

(73) Assignee: Ventiva, Inc., Milpitas, CA (US)

(21) Appl. No.: 15/864,676

(22) Filed: Jan. 8, 2018

Related U.S. Application Data
(60) Provisional application No. 62/447,428, filed on Jan. 17, 2017.

(51) Int. Cl. H05K 7/20

(52) U.S. Cl. CPC H05K 7/20172; H05K 7/20209

(57) ABSTRACT

An apparatus for cooling a portable electronic device during use includes a first cavity having an intake port for drawing air into the first cavity and a second cavity proximate the first cavity having an output port, wherein upon installation of a portable electronic device, a surface of the portable electronic device defines a portion the second cavity. An ionic wind generator separates the first cavity and the second cavity, and generates an airstream to draw air into the intake port, wherein the airstream passes between the first cavity and the second cavity to be directed upon the surface of the electronic device, and exhausted through the output port thereby dissipating heat generated by the portable electronic device.

### RELATED APPLICATIONS

This application claims priority to Provisional Patent Application Ser. No. 62/447,428 filed Jan. 17, 2017, the entirety of which is incorporated herein by reference.

### FIELD OF INVENTION

This invention relates to dissipating heat from a portable electronic device during use, and more particularly to a light-weight, portable cooling apparatus that uses a solid state ionic wind generator to generate an airstream within the cooling apparatus, and directing the airstream along a surface of the portable electronic device during use to enhance cooling, improve performance, and avoid overheating and shut down of the device.

### BACKGROUND

Portable electronic devices have become increasingly popular for a wide variety of activities. Such devices continue to be reduced in size to increase their portability, while simultaneously increasing their functionality and consequently, power demands also have also necessarily been increased. The increased power demands result in increased operating temperatures of these devices. Since increased operating temperatures can degrade the performance of the devices and the length of a useable charge in an associated battery, it is important to efficiently and effectively remove heat generated by the devices, while not detracting from their portability.

### SUMMARY

The present invention is directed to a cooling apparatus for a portable electronic device having a first cavity with a first port, a second cavity proximate the first cavity with a second port, wherein upon installation of a portable electronic device, a surface of the portable electronic device defines a portion the second cavity, and an ionic wind generator separating the first cavity from the second cavity for generating an airstream to draw air into one of the first and the second ports, wherein the airstream passes between the first cavity and the second cavity to be directed upon the surface of the electronic device, and exhausted through the other of the first and second ports thereby dissipating heat generated by the portable electronic device. The apparatus may include a battery for providing power to at least the ionic wind generator. There may be a controller for regulating the ionic wind generator. There may be a sensor in communication with the controller for monitoring the temperature of the electronic device such that the controller turns the ionic wind generator on when the device reaches a first predetermined temperature threshold. The controller may turn the ionic wind generator off when the device reaches a second predetermined temperature threshold. There may be a projection for securing the portable electronic device. Upon installation of the portable electronic device, a second surface of the electronic device may define a portion of the first cavity. There may be a third cavity for housing the controller. The third cavity may be proximate the first cavity and have an intake port and an output port connected to the first cavity for drawing a portion of the airstream through the third cavity to cool the controller.

In another embodiment there is provided a housing for receiving a portable electronic device having a first cavity for housing an ionic air moving device for generating an airstream, the first cavity having an air intake for allowing the airstream to draw air into the first cavity. There is a second cavity adjacent to the first cavity, wherein at least of portion of the second cavity is defined by a surface of the portable electronic device when received, the second cavity having an output port for exhausting the airstream out of the second cavity. An airflow path is defined by the air intake, the first cavity, the second cavity and the output port to enable air to flow from the air intake of the first cavity, between the first and second cavities and onto the surface of the portable electronic device. The airstream is exhausted from the second cavity through the output port in order to allow the airstream to draw heat away from the portable electronic device. The first and second cavities may be connected by the air intake or the first and second cavities may be connected by the output port. There may be a controller for regulating the ionic wind generator. There may be a sensor in communication with the controller for monitoring a temperature of the portable electronic device such that the controller may turn the ionic air mover on when the device reaches a first predetermined temperature threshold. The controller may turn the ionic air mover off when the portable electronic device reaches a second predetermined temperature threshold.

In yet another embodiment there is provided a method for cooling a portable electronic device by generating an ionic air stream for drawing air into one of a first cavity and a second cavity, wherein the first cavity is proximate the second cavity, and a portion of one of the first and second cavities is defined by a surface of the portable electronic device, passing the airstream between the first and second cavities wherein the air stream is directed onto the surface of the portable electronic device; and exhausting the air stream out of the other of the first and second cavities thereby dissipating heat from the portable electronic device.

### BRIEF DESCRIPTION OF THE DRAWINGS

The foregoing and other objects, features and advantages of embodiments of the present inventive concepts will be apparent from the more particular description of preferred embodiments, as illustrated in the accompanying drawings in which like reference characters refer to the same elements throughout the different views. The drawings are not necessarily to scale, emphasis instead being placed upon illustrating the principles of the preferred embodiments.

FIG. 1 is a perspective view of an embodiment of the cooling apparatus of the present invention for cooling a rechargeable, portable electronic device during use;

FIG. 2 is an exploded, perspective view of the apparatus of FIG. 1 exposing the various components of the cooling apparatus of the present invention;

FIG. 3 is a perspective cross-sectional view of an embodiment of the present invention;

FIG. 4A is top plan view of an embodiment of the cooling apparatus according to present invention;

FIG. 4B is a top plan view of an embodiment of the cooling apparatus according to the present invention;

FIG. 4C is a perspective view of an embodiment similar to FIG. 4B; and

FIG. 5 is a cross-sectional, side view of an embodiment similar to FIG. 4C.

### DETAILED DESCRIPTION OF EMBODIMENTS

In the following description, references are made to the removal of heat from portable, rechargeable electronic devices for example, action-oriented cameras. It will be understood, however, that the cooling apparatus of the present invention may be applied to numerous types of portable electronic devices that produce heat during operation that can adversely affect the operation of the device. Such devices may include those powered by a rechargeable battery or discrete, replaceable batteries.

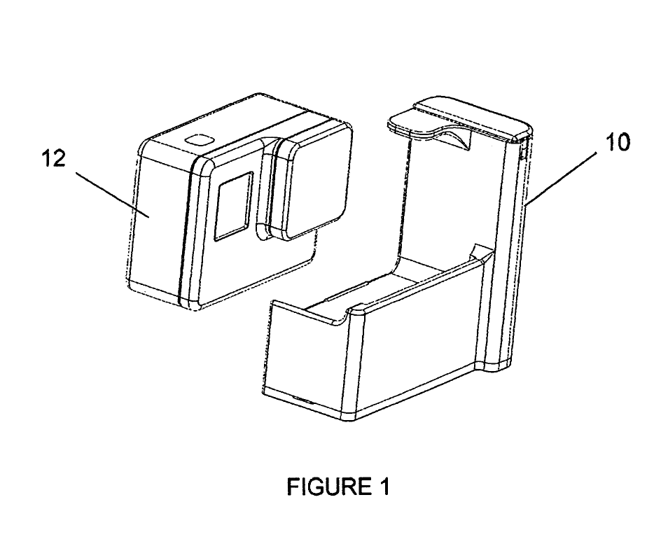

Referring now to FIG. 1 there is shown a perspective view of a housing 10 of a cooling apparatus according to the present invention for receiving and cooling a portable electronic device 12, such as a rechargeable action camera. Most electronic devices already have some type of heat dissipating solution incorporated into them. For example, a GoPro® action camera has a heat sink (not shown) incorporated into its face, however sometimes these solutions still do not provide sufficient cooling, thus additional cooling can improve the operation of the device while not detracting from its portability.

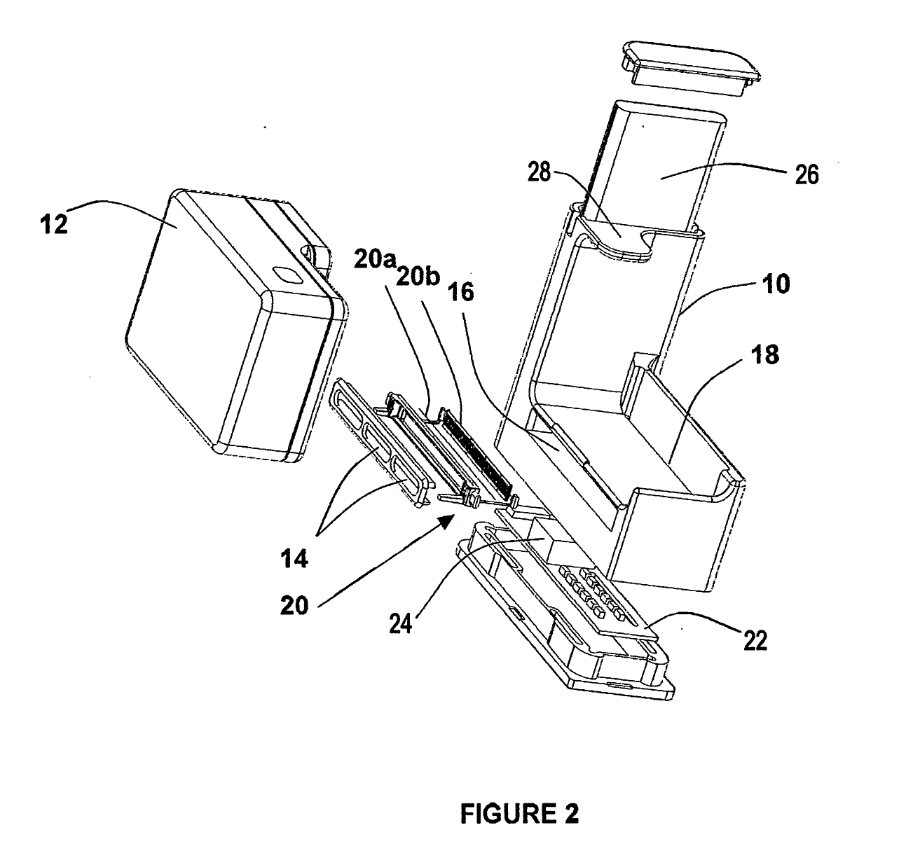

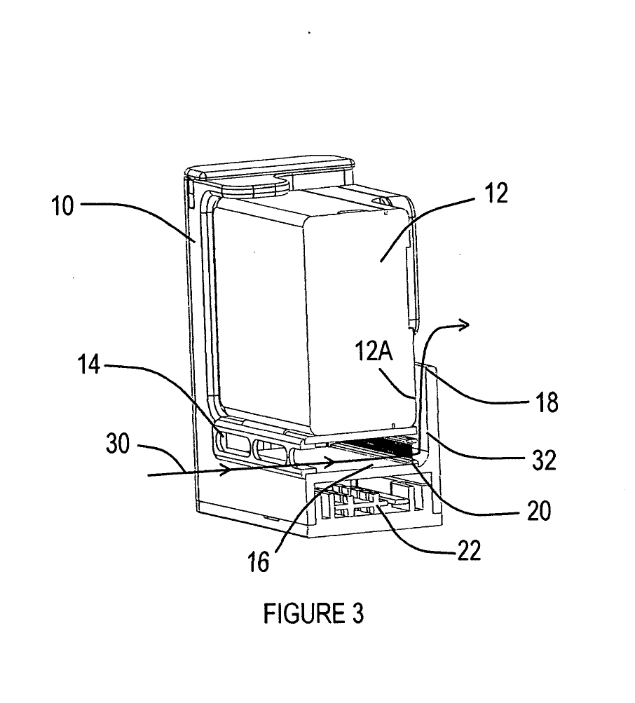

As shown in FIG. 2, housing 10 may include one or more air intake ports 14, a cavity 16 and one or more air output ports 18. An ionic wind generator 20, comprising an emitter 20a and a collector 20b, creates a pressure within cavity 16 by ionizing the air around emitter 20a which is impelled toward collector 20b, creating an airstream for drawing air into cavity 16 through air intake ports 14. The airstream is ultimately exhausted through output port 18 as it is directed upon a surface of portable electronic device 12, as discussed in more detail with respect to FIG. 3. In a preferred embodiment ionic wind generator 20 may be one such as is available from Ventiva, Inc. of California.

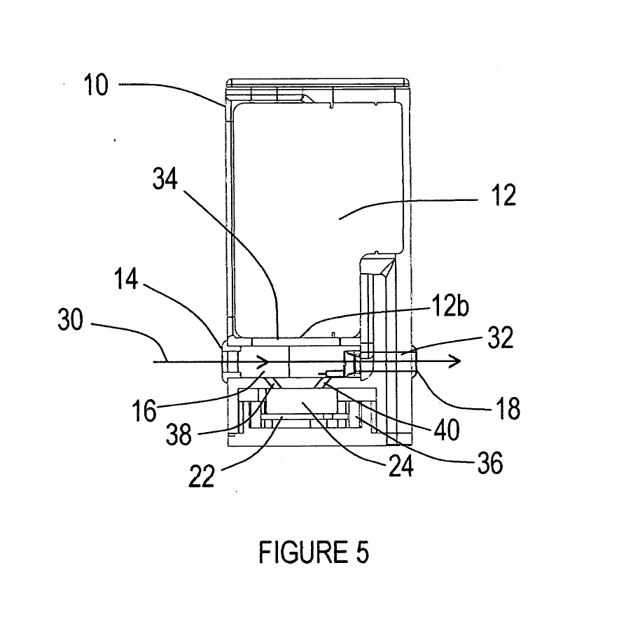

Ionic wind generator 20 is operated by control a board 22, and in particular a controller 24, which may be, for example, a PIC12F1822 (or, an 8-bit) microprocessor available from Microchip Technology, Inc. However, there are various microprocessors available for use in the present invention, the operation of which will be further described with respect to FIG. 5. Cooling apparatus 10 may also include a battery 26, which may be a rechargeable battery, such as a lithium ion battery or the like, as well as discrete batteries, such as multiple AA or AAA batteries for powering control board 22. Apparatus 10 may also comprise a projection such as tab 28 for frictionally securing or affixing portable electronic device 12 to cooling apparatus 10. Other methods for securing portable device 12 to cooling apparatus 10 will be readily recognized without detracting from the scope of the invention.

Referring now to FIG. 3, as the temperature of portable electronic device 12 increases a sensor (not shown) communicates with controller 24 on control board 22. When the sensor communicates a temperature that exceeds a predetermined threshold, controller 24 turns on ionic wind generator 20 which generates an airstream 30 that is drawn through air intake port 14 into cavity 16. Alternatively, when the portable electronic device 12 becomes active, the control board detects that active cooling will be required within a predetermined time interval and can initiate cooling at predetermined intervals of time. A second cavity 32 is proximate to cavity 16 and separated by ionic wind generator 20. Ionic wind generator 20 is oriented such that airstream 30 passes from first cavity 16 into second cavity 32. When electronic device 12 is affixed to cooling apparatus 10, at least a portion of second cavity 32 is defined by a surface 12a of portable electronic device 12. As discuss above portable electronic devices such as portable electronic device 12 typically include at least one passive heat sink located at or near the surface of the device for radiating heat produced by the device to the ambient air. Thus, as airstream 30 is directed along surface 12a, and thus the area where passive heat sink is located, cooling of the device is enhanced, improving operation of portable electronic device 12 while in use, and extend the battery's power. As airstream 30 is directed upon surface 12a, some of the heat from device 12 is exhausted via output port 18. When the temperature of portable electronic device 12 has fallen below a second threshold temperature, controller 24 will turn off ionic wind generator 20. This cycle continues as portable electronic device 12 is in use.

It should be noted that ionic wind generator 20 can be oriented to direct airstream 30 in the opposite direction as well, drawing air into cavity 16 from cavity 32. Irrespective of the direction of airstream 30, the resulting airstream is directed across surface 12a to dissipate some of the heat generated by the portable electronic device 12 and enhance cooling of the device 12 to improve performance and prevent overheating, which can cause the device 12 to shut down prematurely (as a safety measure), thereby interrupting operation.

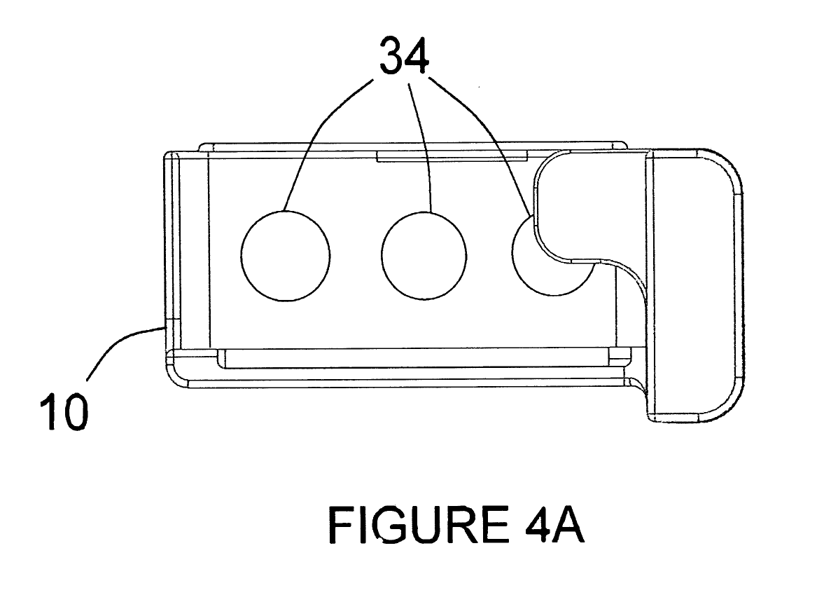

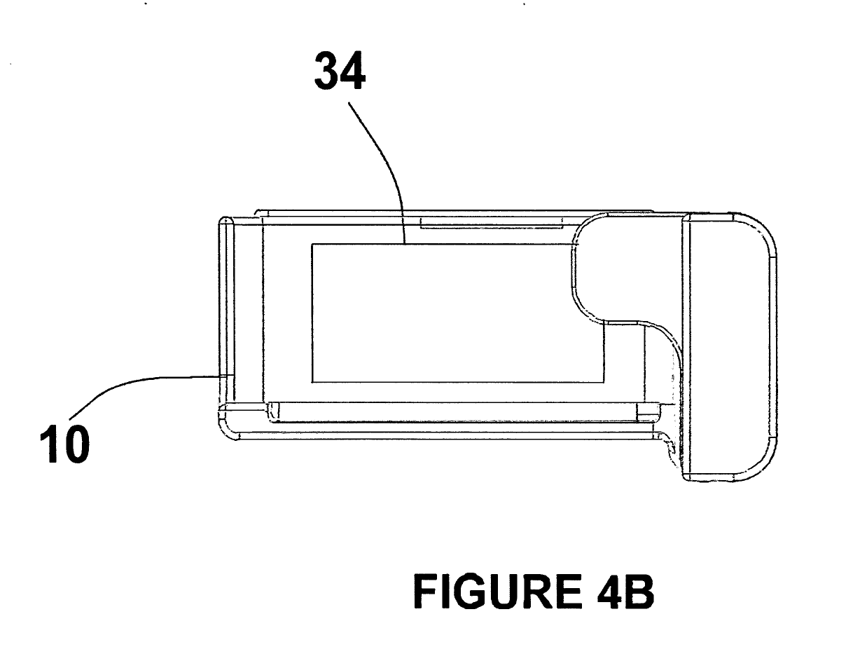

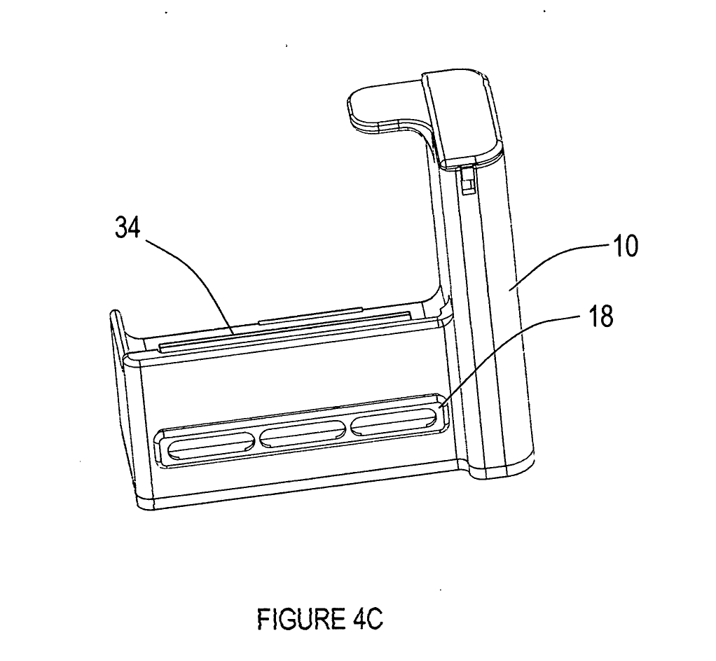

Referring now to FIG. 4A, there is shown a top view of another embodiment of cooling apparatus 10 according an aspect of the present invention where air is directed on the bottom surface of portable device 12 (not shown) through one or more holes 34. Thus, if a passive heat sink is located at the base of portable electronic device 12, material can be removed from cooling apparatus 10 such that the airstream can be directed along the base of the device, instead of, or in addition to the surface 12a of FIG. 3.

Similarly, FIG. 4B is top view of yet another embodiment of the present invention where airstream 30 can be directed along a greater surface area of portable electronic device 12 when installed. As Shown in FIG. 4C, rather than being directed along the front of electronic device 12 and exhausted, the airstream may be exhausted directly from the front of cooling apparatus 10 if only the base of the device is being cooled.

As shown in the cross section of FIG. 5, airstream 30 is drawn into first cavity 16 through intake port 14, along a surface 12b of portable electronic device 12, and passed into second cavity 32 to output port 18. Again, the orientation of ionic air mover 20 determines the direction of airstream 30, but, as will be clear to one of skill in the art, regardless of the orientation of airstream 30 directed along surface 12b, heat will be removed from portable electronic device 12. Thus, irrespective of the location of the passive heat sink in portable electronic device 12, cooling apparatus 10 can enhance cooling and improve performance during use. A third cavity 36, adjacent and below first cavity 16, houses control board 22. Third cavity 36 may comprise at least one input port 38 and at least one output port 40 connected to first cavity 16. Input and output ports 38 and 40 allow a portion of airstream 30 to pass through third cavity 36 to also provide cooling to control board 22 and its components as well.

Having thus described several aspects of various embodiments of the present invention concepts, it will be appreciated that various combinations of the disclosed embodiments readily occur to those skilled in the art. Such alterations, modifications, and combinations are intended to be part of this disclosure, and are intended to be within the spirit and scope of the inventive concepts. Accordingly, the foregoing description and drawings are by way of example only.

What is claimed is:

1. A cooling apparatus for a portable electronic device comprising:
a first cavity having a first port;
a second cavity proximate the first cavity having a second port, wherein upon installation of a portable electronic device, a surface of the portable electronic device defines a portion the second cavity; and
an ionic wind generator, separating the first cavity and the second cavity, for generating an airstream to draw air into one of the first and second ports, wherein the airstream passes between the first cavity and the second cavity to be directed upon the surface of the electronic device, and is exhausted through the other of the first and second ports, thereby dissipating heat generated by the portable electronic device.

2. The apparatus of claim 1, further comprising a battery for providing power to at least the ionic wind generator.

3. The apparatus of claim 2 further comprising a controller for regulating the ionic wind generator.

4. The apparatus of claim 3 further comprising a sensor in communication with the controller for monitoring the temperature of the electronic device such that the controller turns the ionic wind generator on when the device reaches a first predetermined temperature threshold.

5. The apparatus of claim 4 wherein the controller turns the ionic wind generator off when the device reaches a second predetermined temperature threshold.

6. The apparatus of claim 1 further comprising a projection for securing the portable electronic device.

7. The apparatus of claim 1 wherein the first port is an intake port for drawing air into the first cavity and the second port is an output port for exhausting air out of the second cavity.

8. The apparatus of claim 1 wherein upon installation of the portable electronic device, a second surface of the electronic device defines a portion the first cavity.

9. The apparatus of claim 3 further comprising a third cavity for housing the controller.

10. The apparatus of claim 9 wherein the third cavity is proximate the first cavity and comprises an intake port and an output port connected to the first cavity such that a portion of the airstream can pass through the third cavity to cool the controller.

11. A housing for receiving a portable electronic device comprising:
a first cavity for housing an ionic air moving device for generating an airstream, the first cavity having an air intake for allowing the airstream to draw air into the first cavity;
a second cavity adjacent to the first cavity, wherein at least of portion of the second cavity is defined by a surface of the portable electronic device when received, and having an output port for exhausting the airstream out of the second cavity; and
an airflow path defined by the air intake, the first cavity, the second cavity and the output port to enable air to flow from the air intake of the first cavity, between the first and second cavities and onto the surface of the portable electronic device, and exhausted through the output port in order to allow the airstream to draw heat away from the portable electronic device.

12. The housing of claim 11 wherein the first and second cavities are connected by the air intake.

13. The housing of claim 11 wherein the first and second cavities are connected by the output port.

14. The housing of claim 11 further comprising a controller for regulating the ionic wind generator.

15. The housing of claim 14 further comprising a sensor in communication with the controller for monitoring a temperature of the portable electronic device such that the controller turns the ionic air mover on when the device reaches a first predetermined temperature threshold.

16. The housing of claim 15 wherein the controller turns the ionic air mover off when the portable electronic device reaches a second predetermined temperature threshold.

17. A method for cooling a portable electronic device, the method comprising:
generating an ionic air stream for drawing air into one of a first cavity and a second cavity, wherein the first cavity is proximate the second cavity, and a portion of one of the first and second cavities is defined by a surface of the portable electronic device;
passing the airstream between the first and second cavities wherein the air stream is directed onto the surface of the portable electronic device; and
exhausting the air stream out of the other of the first and second cavities thereby dissipating heat from the portable electronic device.
